(19) United States
(12) Patent Application Publication
(10) Pub. No.: US 2025/0393134 A1
(43) Pub. Date: Dec. 25, 2025

(54) METHODS OF FORMING A STRUCTURE ON A SUBSTRATE AND ASSOCIATED METHODS OF FILLING A RECESSED FEATURE ON A SUBSTRATE

(71) Applicant: ASM IP Holding B.V., Almere (NL)

(72) Inventor: Krzysztof Kamil Kachel, Queen Creek, AZ (US)

(21) Appl. No.: 19/240,100

(22) Filed: Jun. 17, 2025

Related U.S. Application Data
(60) Provisional application No. 63/662,026, filed on Jun. 20, 2024.

(51) Int. Cl. H05K 3/00; H05K 3/12

(52) U.S. Cl. CPC H05K 3/0082; H05K 3/1258; H05K 2203/095; H05K 2203/10

(57) ABSTRACT

Methods for filling a recessed feature on a substrate employing metal sequential infiltration synthesis processes are disclosed. The disclosed methods include forming an organic layer within a recessed feature and introducing metal species into the organic layer to allow the formation of a metal seed layer. A bulk metal layer can subsequently be formed from the metal seed layer to fill the recessed feature.

### CROSS-REFERENCE TO RELATED APPLICATIONS

This application is a nonprovisional of, and claims priority to and the benefit of, U.S. Provisional Patent Application No. 63/662,026, filed Jun. 20, 2024 and entitled “METHODS OF FORMING A STRUCTURE ON A SUBSTRATE AND ASSOCIATED METHODS OF FILLING A RECESSED FEATURE ON A SUBSTRATE,” which is hereby incorporated by reference herein.

### FIELD

The present disclosure relates generally to the field of semiconductor processing methods, associated structures, and to the field of device and integrated circuit manufacture. More particularly the present disclosure generally relates to methods of forming a structure on a substrate employing a sequential infiltration synthesis process and to associated methods for filling a recessed feature on a substrate employing such sequential infiltration synthesis processes.

### BACKGROUND

Fabrication processes for forming device structures, such as, for example, transistors, memory elements, and integrated circuits, are wide ranging and may include deposition, etch, lithography, and doping processes, amongst others.

As semiconductor devices employ ever decreasing feature sizes the lithography processes employed in fabricating such devices become ever more complex and cost prohibitive. As such methods for forming features on a substrate with either a reduced number of lithography steps or even without the need for lithography processes have become increasingly attractive.

A particular fabrication process which could benefit from a lithography-free process involves the patterning and deposition of a material into a recessed feature on a substrate, thereby filling the recessed feature (or gap) with the material, a process commonly referred to as “gap-fill.” For example, a non-planar substrate may comprise a multitude of recessed features, such as vertical recessed features, disposed between protruding portions of a substrate surface, or indented recessed features formed into a substrate surface.

Deposition methods such as high-density plasma (HDP), sub-atmospheric chemical vapor deposition (SACVD), and low-pressure chemical vapor deposition (LPCVD) have been employed in gap-fill processes, but these and other processes commonly do not achieve the desired gap-fill results. Accordingly, methods are desired for forming structures on a substrate as well as filling recessed features with a reduced number of lithography processes, or even without employing lithography process.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various embodiments of the present disclosure relate to methods for forming a structure on a substrate employing sequential infiltration synthesis process. In addition, the various embodiments relate to methods for filling (or at least partially filling) a recessed feature on a substrate employing sequential infiltration synthesis process. In addition, the various embodiments relate to methods for forming semiconductor structures with a reduced number of photolithography processes.

In one aspect, a method for forming a structure on a substrate is provided, the method comprising: at a substrate within a reaction chamber, the substrate including a photosensitive layer on a surface of the substrate; irradiating select regions of the photosensitive layer with electromagnetic radiation thereby forming a first region having a first concentration of —OH groups and a second region having a second concentration of —OH, wherein the first concentration of —OH groups is greater than the second first concentration of —OH groups; performing a sequential infiltration synthesis process thereby forming a first infiltrated photosensitive layer in the first region, a non-infiltrated layer disposed below the first infiltrated photosensitive layer, and a second infiltrated photosensitive layer in the second region; removing the first infiltrated photosensitive layer; removing the non-infiltrated layer; and removing a residual component of the second infiltrated photosensitive layer thereby forming a metal containing layer on the surface of the substrate.

In some embodiments performing the sequential infiltration synthesis process includes executing one or more repeated infiltration cycles, each infiltration cycle including at least introducing a first reactant comprising a metal species into the reaction chamber.

In some embodiments each infiltration cycle further includes introducing a second reactant into the reaction chamber, the second reactant including one or more of an oxygen reactant, a nitrogen reactant, or a carbon reactant.

In some embodiments the metal species comprises one or more of aluminum, hafnium, titanium, niobium, tungsten, cobalt, ruthenium, silicon, germanium, and molybdenum.

In some embodiments removing the first infiltrated photosensitive layer includes contacting the first infiltrated photosensitive layer with an etchant to expose the non-infiltrated layer.

In some embodiments removing the non-infiltrated layers and the residual component of the second infiltrated photosensitive layer includes contacting the non-infiltrated layer and the second infiltrated photosensitive layer with a plasma generated from an oxygen containing gas.

In another aspect, a method of filling a recessed feature on a substrate is provided, the method comprising: at a substrate within a reaction chamber, the substrate including the recessed feature and a photosensitive layer disposed over the recessed feature; irradiating the photosensitive layer with electromagnetic radiation having a wavelength equal to or less than an upper dimension of the recessed feature thereby forming a first region in the photosensitive layer having a first concentration of —OH groups and a second region in the photosensitive layer having a second concentration of —OH, wherein the first concentration of —OH groups is greater than the second first concentration of —OH groups; performing a sequential infiltration synthesis process thereby forming a first infiltrated photosensitive layer in the first region, a non-infiltrated layer disposed below the first infiltrated photosensitive layer, and a second infiltrated photosensitive layer in the second region; removing the first infiltrated photosensitive layer; removing the non-infiltrated layer; removing a residual component of the second infiltrated photosensitive layer to form a metal containing layer disposed at a lower surface of the recessed feature; and forming a bulk layer directly on the metal containing layer, wherein the bulk layer fills the recessed feature.

In some embodiments performing the sequential infiltration synthesis process includes executing one more repeated infiltration cycles, each infiltration cycle including at least introducing a first reactant comprising a metal precursor including a metal species into the reaction chamber.

In some embodiments each infiltration cycle further includes introducing a second reactant into the reaction chamber, the second reactant including one or more of an oxygen reactant, a nitrogen reactant, or a carbon reactant.

In some embodiments the metal species includes one or more of aluminum, hafnium, titanium, niobium, tungsten, cobalt, ruthenium, silicon, germanium, and molybdenum.

In some embodiments the photosensitive layer includes an organic layer.

In some embodiments the residual component includes a residual organic component and removing the residual organic component includes contacting the residual organic component with a plasma generated from an oxygen containing gas.

In some embodiments forming the bulk layer directly on the metal containing layer includes depositing the bulk layer by a cyclical deposition process.

In some embodiments the bulk layer comprises one or more of a metal, a metal oxide, a metal nitride, and a metal carbide.

In some embodiments the bulk layer and the metal containing layer both include the metal species.

In some embodiments the bulk layer is different to the metal containing layer.

In some embodiments the method further includes thermally treating the photosensitive layer in an ammonia (NH₃) ambient prior to performing the sequential infiltration synthesis process.

In another aspect, a lithography-free method of bottom-up gap filling of a recessed feature on a substrate is provided, the method comprising: at a substrate within a reaction chamber, the substrate including an organic photosensitive layer disposed on the recessed feature, wherein the recessed feature includes an upper dimension, a lower surface, and an upper surface; irradiating the organic photosensitive layer with electromagnetic radiation having a wavelength equal to or less than the upper dimension of the recessed feature thereby forming a first region in the organic photosensitive layer having a first concentration of —OH groups and a second region in the organic photosensitive layer having a second concentration of —OH, wherein the first concentration of —OH groups is greater than the second first concentration of —OH groups; thermally treating the organic photosensitive layer in an ammonia (NH₃) ambient; performing at least one infiltration cycle of a sequential infiltration synthesis (SIS) sequence to introduce a metal species into the organic photosensitive layer thereby forming a first metal infiltrated layer in the first region, a second metal infiltrated region in the second region, and a non-infiltrated layer, wherein the metal species includes one or more of aluminum, hafnium, titanium, niobium, tungsten, cobalt, ruthenium, silicon, germanium, and molybdenum; contacting the first metal infiltrated layer with an etchant to remove the first metal infiltrated layer; contacting the non-infiltrated layer and a residual organic component of the second metal infiltrated region with a plasma generated from an oxygen reactant thereby at least partially filling the recessed feature with a metal containing layer.

In some embodiments the metal containing layer fills the recessed feature to the upper surface without the formation of a seam.

In some embodiments the metal containing layer partially fills the recessed feature and a bulk layer is deposited on the metal containing layer to fill the recessed feature to the upper surface without the formation of a seam.

For purposes of summarizing the embodiments of the disclosure and their advantages, certain objects and advantages of such embodiments have been described herein above. Of course, it is to be understood that not necessarily all such objects or advantages may be achieved in accordance with any particular embodiment of the disclosure. Thus, for example, those skilled in the art will recognize that the embodiments of the disclosure may be embodied or carried out in a manner that achieves or optimizes one advantage or group of advantages as taught or suggested herein without necessarily achieving other objects or advantages as may be taught or suggested herein.

All of these embodiments are intended to be within the scope of the present disclosure. These and other embodiments will become readily apparent to those skilled in the art from the following detailed description of certain embodiments having reference to the attached figures, the present disclosure not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates a method of forming a structure on a substrate in accordance with one or more embodiments of the disclosure.

FIG. 2 illustrates a structure in accordance with one or more embodiments of the disclosure.

FIG. 3 illustrates a structure in accordance with one or more embodiments of the disclosure.

FIG. 4 illustrates a structure in accordance with one or more embodiments of the disclosure.

FIG. 5 illustrates a structure in accordance with one or more embodiments of the disclosure.

FIG. 6 illustrates a structure in accordance with one or more embodiments of the disclosure.

FIG. 7 illustrates a structure in accordance with one or more embodiments of the disclosure.

FIG. 8 illustrates a method of filling a recessed feature in accordance with one or more embodiments of the disclosure.

FIG. 9 illustrates a structure in accordance with one or more embodiments of the disclosure.

FIG. 10 illustrates a structure in accordance with one or more embodiments of the disclosure.

FIG. 11 illustrates a structure in accordance with one or more embodiments of the disclosure.

FIG. 12 illustrates a structure in accordance with one or more embodiments of the disclosure.

FIG. 13 illustrates a structure in accordance with one or more embodiments of the disclosure.

FIG. 14 illustrates a structure in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas. Precursors and reactants can be gasses. Exemplary seal gasses include noble gasses, nitrogen, and the like. In some cases, the term “precursor” can refer to a compound that participates in the chemical reaction that produces another compound, and particularly to a compound that constitutes a film matrix or a main skeleton of a film; the term “reactant” can be used interchangeably with the term precursor.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The substrate may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may comprise, or may consist at least partially of, a plurality of dispersed atoms on a surface of a substrate and/or may be or may become embedded in a substrate and/or may be or may become embedded in a device manufactured on that substrate. A film or layer may comprise material or a layer with pinholes and/or isolated islands. A film or layer may be at least partially continuous. A film or layer may be patterned, e.g., subdivided, and may be comprised in a plurality of semiconductor devices. A film or layer may be selectively grown on some parts of a substrate, and not on others.

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy, molecular beam epitaxy (MBE), gas source MBE, organometallic MBE, and chemical beam epitaxy, when performed with alternating pulses of precursor(s)/reactive gas(es), and purge (e.g., inert carrier) gas(es). A pulse can comprise exposing a substrate to a precursor or reactant. This can be done, for example, by introducing a precursor or reactant to a reaction chamber in which the substrate is present. Additionally, or alternatively, exposing the substrate to a precursor can comprise moving the substrate to a location in a substrate processing system in which the reactant or precursor is present.

Generally, for ALD processes, during each cycle, a precursor is introduced into a reaction chamber and is chemisorbed onto a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber.

As used herein, a “structure” can be or include a substrate as described herein. Structures can include one or more layers overlying or within the substrate, such as one or more layers formed according to a method as described herein. Full devices or partial device portions can be included within or on structures.

As used herein, the term “recessed feature” may refer to an opening or cavity disposed between surfaces of a non-planar surface. For example, the term “recessed feature” may refer to an opening or cavity disposed between opposing sidewalls or protrusions extending vertically from the surface of a substrate or opposing inclined sidewalls of an indentation extending vertically into the surface of a substrate.

As used herein, the term “seam” may refer to a void line or one or more separated voids formed by the abutment of edges formed in a gap-fill metal. The presence of a “seam” can be confirmed using high magnification microscopy methods, such as, for example, scanning transmission electron microscopy (STEM), and transmission electron microscopy (TEM), wherein if observations reveal a clear vertical void line or one or more vertical voids in a recessed feature filled with a gap-fill metal then a “seam” is deemed to be present.

A number of example materials are given throughout the embodiments of the current disclosure, it should be noted that the chemical formulas given for each of the example materials should not be construed as limiting and that the non-limiting example materials given should not be limited by a given example stoichiometry.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments. In some cases, percentages indicated herein can be relative or absolute percentages.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly, to this, it will be understood the term “under,” “underlying,” or “below” will be construed to be relative concepts.

Various embodiments relate to methods for forming a structure on a substrate and associated methods of filling a recessed feature on a substrate employing sequential infiltration synthesis processes and related structures formed by such methods.

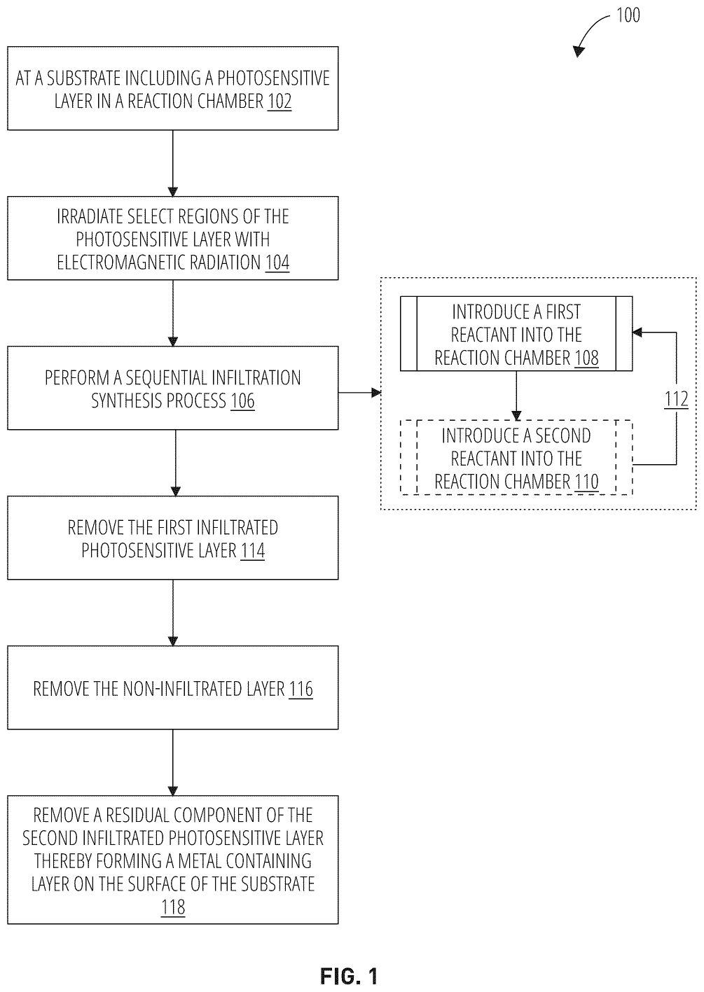

Turning to the figures, FIG. 1 illustrates an exemplary method 100. In brief, method 100 comprises, at a substrate including a photosensitive layer (step 102). Select regions of the photosensitive layer are then irradiated with electromagnetic radiation forming a first region having a first concentration of —OH groups and a second region having a second concentration of —OH, wherein the first concentration of —OH groups is greater than the second first concentration of —OH groups (step 104). A sequential infiltration synthesis process is then performed thereby forming a first infiltrated photosensitive layer in the first region, a non-infiltrated layer disposed below the first infiltrated photosensitive layer, and a second infiltrated photosensitive layer in the second region (step 106). Method 100 may continue by removing the first infiltrated photosensitive layer (step 114) and removing the non-infiltrated layer (step 116). Method 100 may further comprise removing a residual component of the second infiltrated photosensitive layer thereby forming a metal containing layer on the surface of the substrate (step 118).

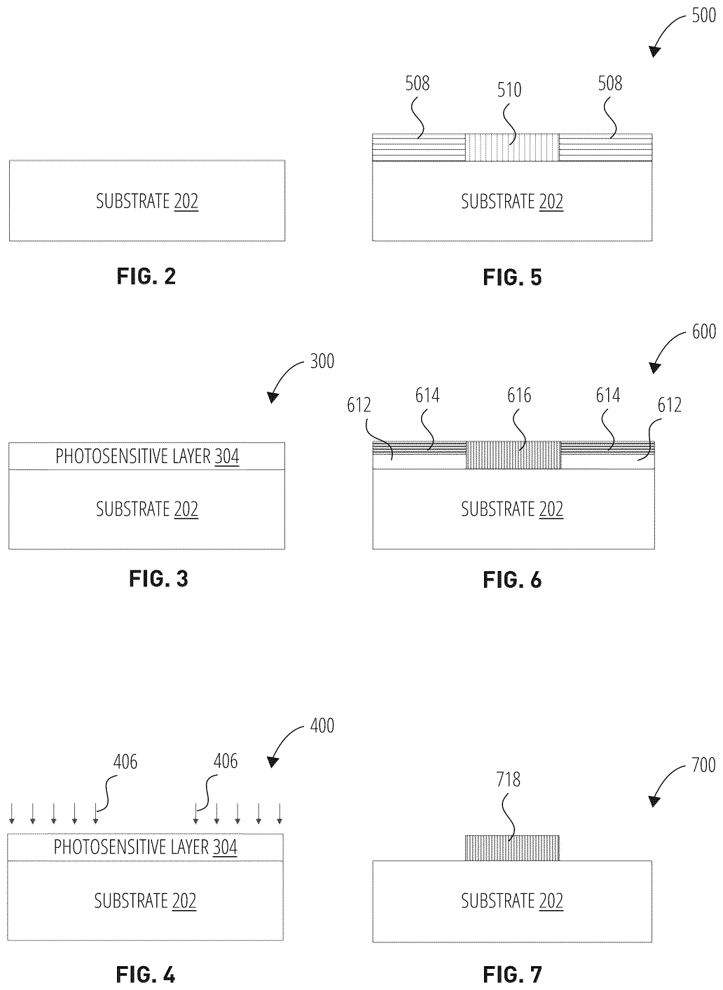

In accordance with examples of the disclosure, FIG. 2 illustrates a substrate 200 upon which a photosensitive layer 304 is formed, as illustrated by structure 300 of FIG. 3. In some embodiments structure 300 may comprise a portion of a device structure, such as, a partially fabricated device structure. In such embodiments the structure 300 may comprise a partially fabricated logic device, memory device, integrated circuit, and the like. In some embodiments the photosensitive layer 304 may comprise at least one of a high-resolution polymer resist or a hardmask material. In accordance with examples of the disclosure, the photosensitive layer may comprise an organic photosensitive layer. In one aspect the photosensitive layer may comprise a high-resolution polymer resist comprising at least one of poly (methyl methacrylate) (PMMA), polystyrene, poly (styrene-block-methyl methacrylate) (PS-b-PMMA), deep ultraviolet (UV) photoresist, 193 nm photoresist (both immersion (193i) and non-immersion (193)) and extreme UV photoresist. In some embodiments the photosensitive layer may comprise a first component and a second component wherein the first component may have at least a first directed self-assembly (DSA) polymer and second component may have a second DSA polymer, wherein the first DSA polymer and the second DSA polymer may be made of PMMA, polystyrene (PS), among other polymers. In another aspect the photosensitive layer may comprise a hardmask comprising at least one of a spin-on-glass, a spin-on-carbon layer, a silicon nitride layer, an anti-reflective-coating layer, or an amorphous carbon layer. The spin-on-glass or spin-on-carbon layer may be provided by spinning a glass or carbon layer on the substrate to provide the hardmask material. In some embodiments the photosensitive layer may be formed on the substrate by a deposition process, such as an atomic layer deposition process, for example.

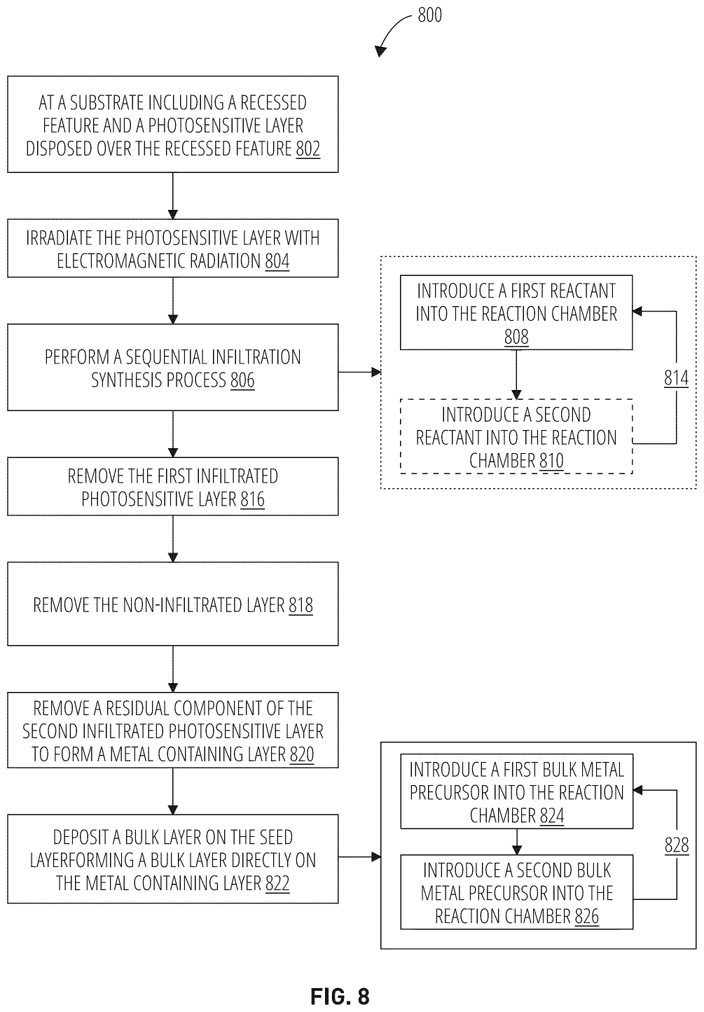

Turning again to method 100 of FIG. 1, step 104 comprises irradiating select regions of the photosensitive layer with electromagnetic (EM) radiation. In accordance with examples of the disclosure, the substrate with the photosensitive layer thereon may be disposed within an apparatus configured for irradiating the photosensitive layer with electromagnetic radiation. In one aspect, irradiating select regions of the photosensitive layer may comprise the use of irradiating apparatus such as extreme ultraviolet lithography apparatus, directing writing apparatus, and the like. In another aspect, irradiating select regions of the photosensitive layer may be performed without the need for such complex irradiating apparatus and processes, as discussed below with reference to method 800 of FIG. 8. In various embodiments the photosensitive layer may be irradiated with electromagnetic radiation having a wavelength of less than 1000 nanometers, less than 750 nanometers, less than 500 nanometers, less than 400 nanometers, less than 300 nanometers, less than 200 nanometers, less 100 nanometers, less than 50 nanometers, less than 25 nanometers, less than 15 nanometers, or equal to or less than 13.5 nanometers. In various embodiments the photosensitive layer may be irradiated with electromagnetic radiation having a wavelength of between 13.5 nanometers and 1000 nanometers.

In accordance with examples of the disclosure, irradiating select regions of the photosensitive layer with electromagnetic radiation may result in the formation of a first region having a first concentration of —OH groups and a second region having a second concentration of-OH. In such examples the first concentration of-OH groups may be greater than the second first concentration of —OH groups.

FIG. 4 illustrates a structure 400 which illustrates the select irradiation of the photosensitive layer 304 with electromagnetic radiation 406 and FIG. 5 illustrates a structure 500 upon completion of the selective irradiating step (e.g., step 104 of method 100). As illustrated in FIG. 5 the select irradiating of the photosensitive layer 304 by electromagnetic radiation 406 (FIG. 4) results in the formation of a first region 508 and a second region 510 (FIG. 5). In accordance with examples of the disclosure, the first region 508 corresponds to the region of the photosensitive layer 304 exposed to electromagnetic radiation 406 (as illustrated in FIG. 4) and the second region 510 corresponds to the region of the photosensitive layer 304 not exposed to electromagnetic radiation 406. In such examples the first region 508 receives a higher illuminance (E) of electromagnetic radiation compared with second region 510. Not to be bound be any theory or mechanism, but it is has been found that irradiating select regions of a photosensitive layer with electromagnetic radiation results in the formation of a higher concentration of hydroxyl groups in the irradiated regions of the photosensitive layer (i.e., the first region 508 of FIG. 5) compared with regions (i.e., the second region 510 of FIG. 5) which are either not irradiated regions, or regions exposed to a lower illuminance of electromagnetic radiation in comparison to the first region 508.

Method 100 may continue with step 106 which comprises performing a sequential infiltration synthesis process. In accordance with examples of the disclosure, performing the sequential infiltration synthesis process may form a first infiltrated photosensitive layer in the first region, a non-infiltrated layer disposed below the first infiltrated photosensitive layer, and a second infiltrated photosensitive layer in the second region. Not to be bound be any theory or mechanism, but it is has been found that regions with a higher concentration of hydroxyl groups (e.g., the first region 508 of FIG. 5) when infiltrated form a surface crust of infiltrated species whereas regions with a lower concentration of hydroxyl groups (e.g., the second region 510 of FIG. 5) can be fully, or more fully, infiltrated with the infiltrated species.

In more detail and in accordance with examples of the disclosure, the sequential infiltration synthesis process (step 106) can be employed to introduce metal species into the photosensitive layer and this can be achieved by optionally thermally treating the photosensitive layer (as described below) and employing an infiltration process to infuse metal atoms into the framework of the photosensitive layer. As a non-limiting example, the sequential infiltration synthesis process can include the sorption of at least a portion of a metal precursor into the photosensitive layer (e.g., the metal precursor dissolves and/or diffuses into the photosensitive layer). The metal precursor can then interact with the photosensitive layer (e.g., via reversible complex formation and/or irreversible chemical reactions) and this interaction between the metal precursor and the photosensitive layer results in the entrapment of the metal species, provided from the metal precursor, within the photosensitive layer forming an infiltrated layer. As discuss above, the first region 508 and the second region 510 are infiltrated to different degrees dependent on the concentration of —OH groups in the first region and the second region.

The sequential infiltration synthesis process (also referred to herein as a SIS process) is illustrated in FIG. 1 by step 106 which includes the sub-step 108 and the optional sub-step 110. In accordance with examples of the disclosure, the SIS process (step 106) comprises executing one more repeated infiltration cycles, each infiltration cycle comprising, introducing a first reactant comprising a metal species into the reaction chamber (sub-step 108). In some embodiments, each infiltration cycle can optionally include, introducing a second reactant into the reaction chamber, the second reactant comprising one or more of an oxygen reactant, a nitrogen reactant, or a carbon reactant.

In accordance with examples of the disclosure, the first reactant (e.g., a metal precursor including a metal species) and the optional second reactant can be introduced into the reaction chamber by pulsing the reactant(s) into the reaction chamber wherein they contact the surfaces of the substrate, including the photosensitive layer. The first reactant and the optional second reactant can be purged from the reaction chamber-e.g., after each pulse and/or upon completion of sub-step 108, sub-step 110, and/or after each infiltration cycle. In some embodiments, the sub-steps 108 and 110 can be repeated as illustrated by cycle loop 112. For example, an infiltration cycle can be performed 1 or more times, 2 or more times, 3 or more times, 5 or more times, 10 or more times, 25 or more times, or between 1 and 25 times. Further, sub-steps 108 and 110 can be initiated and/or terminated in any order. Yet further, each infiltration cycle can include multiple repetitions of sub-step 108 and/or sub-step 110 prior to proceeding to the subsequent sub-step(s) of the infiltration cycle. In some embodiments, each infiltration cycle can also include one or more additional sub-steps which can be performed during each infiltration cycle or during select infiltration cycles of the sequence.

In accordance with examples of the disclosure, the first reactant may comprise a metal precursor containing a metal species. In some embodiments the metal species may comprise a semi-metal species, such as, silicon and germanium, for example. In some embodiments the metal species may comprise an elemental metal species. In such embodiments the metal species may be selected from one or more the transition metals. In some embodiments the metal precursor contains metal species comprising one or more of aluminum, hafnium, titanium, niobium, tungsten, cobalt, ruthenium, and molybdenum. In a particular example the metal precursor comprises an aluminum species (i.e., elemental aluminum). In an additional example the metal precursor comprises a titanium species (i.e., elemental titanium). In an additional example the metal precursor comprises a molybdenum species (i.e., elemental molybdenum). In some embodiments the metal precursor comprises a metal halide precursor. In some embodiments the metal halide precursor comprises at least of a metal fluoride, a metal chloride, a metal bromide, or metal bromide. In some embodiments the metal chloride precursor comprises a metal oxychloride precursor. In some embodiments the metal precursor comprises a metal-organic precursor, where the metal-organic precursor contains one or more of the metal species disclosed above. In particular examples the metal species are introduced directly without requiring the introduction of a second reactant. In such examples the step of introducing the metal precursor into the reaction chamber (sub-step 108) may be performed multiple times, with or without intervening purge cycles.

As a non-limiting example, the metal precursor can contain aluminum species which are infiltrated into the photosensitive layer by introducing into the reaction chamber at least one of trimethyl aluminum (TMA), dimethylaluminumchloride, aluminum trichloride (AICI 3), dimethylaluminum isopropoxide (DMAI), tris(tertbutyl)aluminum (TTBA), tris(isopropoxide)aluminum (TIPA), and triethyl aluminum (TEA).

As a further non-limiting example, the metal precursor can contain titanium species which are infiltrated into the organic layer by introducing into the reaction chamber at least one of TiCl₄, TiI₄, TiF₄, or a titanium metal-organic precursor.

As a further non-limiting example, the metal precursor can contain molybdenum species which are infiltrated into the organic layer by introducing into the reaction chamber at least one of MoCl₅, MoF₆, MoO₂Cl₂, MoOCl₄, or a molybdenum metal-organic precursor.

In accordance with additional examples of the disclosure, a second reactant is optionally introduced into the reaction chamber by sub-step 110. In such examples the second reactant may comprise one or more of an oxygen reactant, a nitrogen reactant, a carbon reactant, and a reducing agent. In some embodiments the oxygen reactant may include, but is not limited to, water, hydrogen peroxide, and mixtures thereof. In some embodiments the nitrogen reactant may include, but is not limited to, ammonia (NH₃), hydrazine (N₂H₄), alkyl-hydrazine derivates, and mixtures thereof. In some embodiments the carbon reactant may include, but is not limited to, acetylene, ethylene, alkyl halide compounds, alkene halide compounds, metal alkyl compounds, and mixtures thereof. Exemplary alkyl halide compounds include CX₄, CHX₃, CH₂X₂, CH₃X, where X═F, CI, Br, or I. Exemplary alkene halide compounds include C₂H₃X, C₂H₂X₂, C₂HX₃, and C₂X₄, where X═F, Cl, Br, or I. Exemplary alkyne halide compounds include C₂X₂ and HC₂X, where X═F, Cl, Br, or I. In some embodiments, the infiltrated carbon component may be provided as a component of the first reactant. For example, the first reactant may comprise a compound including a metal species and a carbon component, such as, for example, when employing a metalorganic/organometallic compound as the first reactant. In such examples, introducing a carbon reactant to the reaction chamber may be performed by either sub-step 108 and/or sub-step 110 of the SIS process (step 106). In some embodiments the reducing agent may include, but is not limited to, forming gas (H₂+N₂), ammonia (NH₃), hydrazine (N₂H₄), molecular hydrogen (H₂), hydrogen atoms (H), a hydrogen plasma, alcohols, aldehydes, carboxylic acids, boranes, amines, and mixtures thereof.

In accordance with examples of the disclosure, performing the sequential infiltration synthesis process (step 106) may result in the formation of a first infiltrated photosensitive layer in the first region, a non-infiltrated layer disposed below the first infiltrated photosensitive layer, and a second infiltrated photosensitive layer in the second region. FIG. 6 illustrates a structure 600 which comprises the structure 500 of FIG. 5 post-infiltration. As illustrated in FIG. 6, the structure 600 includes a first infiltrated photosensitive layer 614 (i.e., corresponding to the surface of the first region), and a second infiltrated photosensitive layer 616 (i.e., corresponding to the second region) In some embodiments, a non-infiltrated layer 612 may be disposed below the first infiltrated photosensitive layer 614.

In accordance with examples of the disclosure, method 100 (FIG. 1) further comprises removing the first infiltrated photosensitive layer (step 114). In such examples the first infiltrated photosensitive layer may be removed by contacting the first infiltrated photosensitive layer 614 with an etchant. In some embodiments the etchant may be one or more of a wet etchant, a vapor phase etchant, or a plasma-based etchant. In some embodiments the first infiltrated photosensitive layer may be removed by an atomic layer etch (ALE) process. In some embodiments the etchant may comprise a halide-based etchant, such as chlorine-or fluorine-based etchants.

In accordance with examples of the disclosure, method 100 (FIG. 1) further comprises removing the non-infiltrated layer (step 116) and removing a residual component of the second infiltrated photosensitive layer thereby forming a metal containing layer on the surface of the substrate (step 118). In one aspect the non-infiltrated layer may be removed in step 114 by the etchant selected to remove the second infiltrated photosensitive layer. In another aspect the non-infiltrated layer may be removed by step 118, i.e., the process employed to remove the residual component of the second infiltrated photosensitive layer may also remove the non-infiltrated layer.

In accordance with examples of the disclosure, removing the residual component of the second infiltrated photosensitive layer may comprise contacting the second infiltrated photosensitive layer with a plasma generated from an oxygen containing gas. In some embodiments an oxygen, a nitrogen, a hydrogen, or mixture thereof, containing plasma may be used to remove the residual component of the second infiltrated photosensitive layer. For example, a plasma generator can be used to excite oxygen species for effective removal of the residual components. The plasma generator may be supplied with oxygen (O₂) or hydrogen (H₂), or alternatively a gas mixture of hydrogen (H₂) or oxygen (O₂), and nitrogen (N₂). In various embodiments the plasma generator may be supplied with ammonia (NH₃). In various embodiments the plasma generator may be supplied with carbon dioxide (CO₂). In particular examples the plasma etchant for removing the residual component of the second infiltrated photosensitive layer may comprise at least one of oxygen excited species or nitrogen excited species.

FIG. 7 illustrates a structure 700 which comprises the structure 600 (FIG. 6) after the removal of the first infiltrated photosensitive layer, the non-infiltrated layer, and the residual component of the second infiltrated photosensitive layer. In accordance with examples of the disclosure, removing layers 612, 614, and the residual component of 616 (of FIG. 6) forms a metal containing metal containing layer 718 on the substrate 202. In some embodiments the metal containing layer may comprise one or more of a metal, a metal oxide, a metal nitride, and a metal carbide. In some embodiments the metal containing layer may comprise an elemental metal comprising one or more of aluminum, hafnium, titanium, niobium, tungsten, cobalt, ruthenium, and molybdenum. In some embodiments the metal containing layer may comprise a semi-metal comprising one or more of silicon and germanium. In some embodiments the metal containing layer comprise a metal oxide comprising one or more of aluminum oxide, hafnium oxide, titanium oxide, niobium oxide, tungsten oxide, cobalt oxide, ruthenium oxide, and molybdenum oxide. In some embodiments the metal containing layer may comprise a semi-metal oxide comprising one or more of silicon oxide and germanium oxide. In some embodiments the metal containing layer comprise a metal nitride comprising one or more of aluminum nitride, hafnium nitride, titanium nitride, niobium nitride, tungsten nitride, cobalt nitride, ruthenium nitride, and molybdenum nitride. In some embodiments the metal containing layer may comprise a semi-metal nitride comprising one or more of silicon nitride and germanium nitride. In some embodiments the metal containing layer comprise a metal carbide comprising one or more of aluminum carbide, hafnium carbide, titanium carbide, niobium carbide, tungsten carbide, cobalt carbide, ruthenium carbide, and molybdenum carbide. In some embodiments the metal containing layer may comprise a semi-metal carbide comprising one or more of silicon carbide and germanium carbide. As non-limiting examples the metal containing layer may comprise at least one of molybdenum, aluminum oxide, silicon dioxide, and hafnium oxide.

Various additional embodiments of the disclosure provide methods for filling a recessed feature on a substrate. The methods may include lithography-free processes for bottom-up gap filling of a recessed feature on a substrate. Such additional methods may employ irradiating select regions of a photosensitive layer and sequential infiltration synthesis processes, as previously described above, but may also additionally include employing selected wavelengths of the electromagnetic radiation. In such examples, the selected wavelength may not penetrate to the lower surfaces of the recessed features, as described in detail below.

Turning again to the figures, FIG. 8 illustrates an exemplary method 800 for filling a recessed feature on a substrate. Various steps (and associated sub-steps) of method 800 have been described in detail above and therefore the following detailed description will describe in detail the steps of method 800 which comprise different embodiments to those previously described.

In accordance with example embodiments, method 800 (FIG. 8) comprises, providing and/or at a substrate comprising a recessed feature and a photosensitive layer disposed over the recessed feature (step 802). In accordance with examples of the disclosure, the substrate may comprise a non-planar substrate including a recessed feature (or a plurality of recessed features).

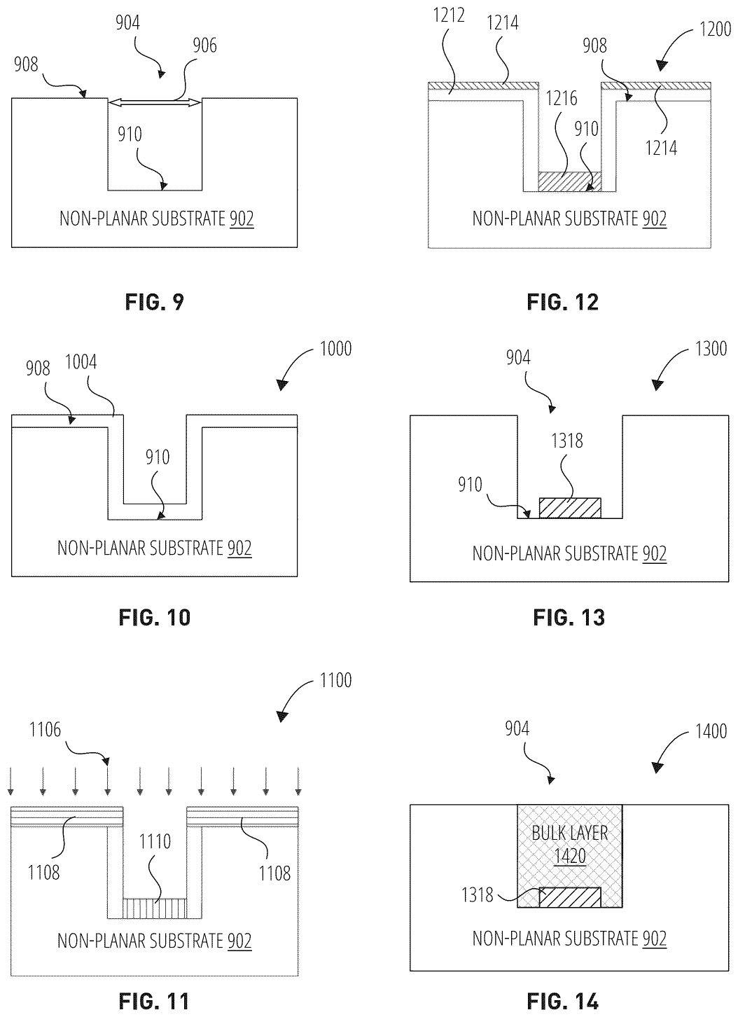

FIG. 9 illustrates an exemplary non-planar substrate 902 which includes a recessed feature 904. In accordance with examples of the disclosure, recessed feature 904 includes an upper dimension 906 defining the opening dimension of the upper portion of the recessed feature. As a non-limiting example, the upper dimension 906 may define a diameter of the upper portion of the recessed feature 904. In some embodiments the upper dimension is less than 1000 nanometers, less than 750 nanometers, less than 500 nanometers, less than 400 nanometers, less than 300 nanometers, less than 200 nanometers, less 100 nanometers, less than 50 nanometer, less than 25 nanometers, less than 15 nanometers, less than 12 nanometers, less than 8 nanometers, or between 8 nanometers and 1000 nanometers.

Although the non-planar substrate 902 is illustrated in FIG. 9 as including a single recessed feature 904, it should be appreciated that the methods provided are not so limited and substrates including a plurality of recessed features can be filled by the methods disclosed herein. It should also be noted that the cross-sectional profile of the recessed feature 904 is exemplary and that the methods disclosed herein encompass the filing of recessed features with alternative cross-sectional profiles, including, but not limited to, curved, scalloped, V-shaped, tapered, re-entrant, as well as through-silicon-via structures. The recessed feature 904 can also comprise a high aspect ratio feature, such as, for example, a trench structure, a vertical gap, and/or a fin structure. When referring to recessed features having a high aspect ratio, the recessed feature 204 may have an aspect ratio (e.g., the ratio of height to width) that is greater than 2:1, greater than 5:1, greater than 10:1, greater than 25:1, greater than 50:1, or greater than 100:1.

In accordance with examples of the disclosure, a photosensitive layer is disposed over the substrate. In some embodiments the photosensitive layer comprises a conformal photosensitive layer which is disposed on the non-planar substrate and particularly over the recessed feature within the non-planar substrate. In various embodiments the photosensitive layer is formed and comprises materials as previously described above. In some embodiments the photosensitive layer may comprise an organic layer, such as an organic photosensitive layer, for example.

FIG. 10 illustrates a structure 1000 including the non-planar substrate 902 and a photosensitive layer 1004 disposed over the recessed feature 904 and the non-planar substrate 902. As illustrated in FIG. 10 the photosensitive layer 1004 is disposed over the upper surface 908 of the recessed feature 904 and the lower surface 910 of the recessed feature 904, as well as the side walls of the recessed feature.

In alternative embodiments the photosensitive layer may be a non-conformal layer (not shown). In such embodiments, the non-conformal photosensitive layer may fill, or substantially fills, the recessed feature.

In various embodiments, method 800 (FIG. 8) may further comprise irradiating the photosensitive layer with electromagnetic radiation having a wavelength equal to or less than an upper dimension of the recessed feature (step 804) thereby forming a first region in the photosensitive layer having a first concentration of-OH groups and a second region in the photosensitive layer having a second concentration of-OH, wherein the first concentration of —OH groups is greater than the second first concentration of-OH groups. In accordance with examples of the disclosure, irradiating the photosensitive layer with electromagnetic radiation having a wavelength equal to or less than an upper dimension may comprise a blanket exposure of the substrate with the photosensitive layer disposed thereon. In accordance with further examples of the disclosure, the wavelength of the electromagnetic radiation may be selected to be less than the upper dimension of the recessed feature such that the electromagnetic radiation is prevented, or substantially prevented, from penetrating the lower surface of the recessed feature (e.g., lower surface 910 of the recessed feature 904 as illustrated in FIG. 9). In such examples the upper surface 908 (and the corresponding portion of the photosensitive layer disposed thereon) receives a higher illuminance (E) of electromagnetic radiation compared with the lower surface 910 (and the corresponding portion of the photosensitive layer disposed thereon). In such examples the portion of the photosensitive layer disposed on the upper surface of the recessed feature may have a higher concentration of hydroxyl groups compared with the portion of the photosensitive layer disposed on the lower surface of the recessed features which is either not irradiated or is exposed to a lower illuminance of electromagnetic radiation in comparison to the portion of the photosensitive layer disposed on the upper surface. In accordance with examples of the disclosure, the wavelength of the electromagnetic radiation is less than upper dimension of the recessed feature. In such examples the wavelength of the electromagnetic radiation may be less than 1000 nanometers, less than 750 nanometers, less than 500 nanometers, less than 400 nanometers, less than 300 nanometers, less than 200 nanometers, less 100 nanometers, less than 50 nanometer, less than 25 nanometers, less than 15 nanometers, or equal to or less than 13.5 nanometers. In various embodiments the photosensitive layer may be irradiated with electromagnetic radiation having a wavelength of between 13.5 nanometers and 1000 nanometers.

FIG. 11 illustrates a structure 1100 which comprises the structure 1000 (FIG. 10) after irradiating the photosensitive layer with electromagnetic radiation having a wavelength equal to or less than an upper dimension of the recessed feature, i.e., after completion of step 804 of method 800 (FIG. 8). As illustrated in FIG. 11, the electromagnetic radiation 1106 may be blanket wave of electromagnetic (EM) radiation, this is in contrast with the selective electromagnetic radiation 406 of FIG. 4. In addition, structure 1100 includes a first region 1108 of the photosensitive layer having a first concentration of —OH groups disposed on the upper surface of the recessed feature and a second region 1110 of the photosensitive layer having a second first concentration of —OH groups, where the first concentration of —OH groups is greater than the second first concentration of —OH groups.

In various embodiments, method 800 (FIG. 8) may further comprise performing a sequential infiltration synthesis process thereby forming a first infiltrated photosensitive layer in the first region, a non-infiltrated layer disposed below the first infiltrated photosensitive layer, and a second infiltrated photosensitive layer in the second region (step 806 and associated sub-sub-steps 808 and 810, as well cycle loop 814). In some embodiments, performing the sequential infiltration synthesis process (step 806) comprises executing one more repeated infiltration cycles, each infiltration cycle comprising at least introducing a first reactant (sub-step 808) comprising a metal precursor including a metal species into the reaction chamber. In some embodiments, the metal species is selected from a group consisting of one or more of aluminum, hafnium, titanium, niobium, tungsten, cobalt, ruthenium, silicon, germanium, and molybdenum. In some embodiments each infiltration cycle further comprises introducing a second reactant into the reaction chamber, the second reactant comprising one or more of an oxygen reactant, a nitrogen reactant, or a carbon reactant into the reaction chamber (sub-step 812). The SIS process (step 806) of method 800 has been previously described in relation to method 100 and particular to step 106 (and sub-steps 108 and 110) and therefore is not repeated here.

FIG. 12 illustrates a structure 1200 which comprises the structure 1200 after completion of the sequential infiltration synthesis process, i.e., after completion of the step 806 of method 800. As illustrated in FIG. 12 the structure 1200 includes a first infiltrated photosensitive layer 1214 (i.e., corresponding to the surface of the first region disposed above the upper surface 908), and a second infiltrated photosensitive layer 1216 (i.e., corresponding to the second region disposed over the lower surface 910). In some embodiments a non-infiltrated layer 1212 may be disposed below the first infiltrated photosensitive layer 614.

In various embodiments, method 800 may further comprise removing the first infiltrated photosensitive layer (step 818), as previously described with reference to step 114 of method 100.

In various embodiment, method 800 may further comprise removing the non-infiltrated layer 612 (step 820), as previously described with reference to step 116 of method 100.

In various embodiment, method 800 may further comprise removing a residual component of the second infiltrated photosensitive layer to form a metal containing layer disposed at a lower surface of the recessed feature. In some embodiments the residual component comprises a residual organic component (e.g., when the photosensitive layer comprises an organic photosensitive layer) and removing the residual organic component comprises contacting the residual organic component with a plasma generated from an oxygen containing gas or other gases as previously described with reference to step 118 of method 100. In accordance with examples of the disclosure, removing a residual component of the second infiltrated photosensitive layer forms a metal containing layer disposed at a lower surface of the recessed feature. In such examples the metal containing layer comprises one or more a metal, a metal oxide, a metal nitride, and a metal carbide, as previously described above and including all the materials described previously. In some embodiments the metal containing layer may be used as is formed. In alternative embodiments, the metal containing layer may have sufficient thickness to fill the recessed feature. In alternative embodiments, the metal containing layer may comprise a seed layer and the seed layer may be employed as a nucleation layer for the deposition of a bulk layer which may fill, or least partially fill the recessed feature, as described in detail below.

FIG. 13 illustrates a structure 1300 which comprises the structure 1200 (FIG. 12) after the removal of the first infiltrated photosensitive layer 1214, the non-infiltrated layer 1212, and the residual component of the second infiltrated photosensitive layer 1216. In accordance with examples of the disclosure, removing layers 1212, 1214, and the residual component of the second infiltrated photosensitive layer 1216 (of FIG. 12) may form the metal containing layer 1318 on the non-planar substrate 902. In such examples, the metal containing layer 1318 may be formed at the lower surface 910 of the recessed feature 904. In additional examples, the metal containing layer 1318 may substantially fill, or fill, the recessed feature 904 (not illustrated). In some embodiments the metal containing layer 1318 may comprise one or more of a metal, a metal oxide, a metal nitride, and a metal carbide.

In various embodiments, having formed the metal containing layer at the lower surface of the recessed feature, the methods of the disclosure can continue by depositing a bulk layer directly on the metal containing layer, wherein the bulk layer fills the recessed feature. In some embodiments, the bulk layer is deposited employing a cyclical deposition process, wherein the bulk layer fills the recessed feature without the formation of a seam. In some embodiments, the bulk layer is deposited by a cyclical deposition process. In some embodiments, the bulk layer is deposited by a selective cyclical deposition process.

In various embodiments, method 800 (FIG. 8) may therefore further comprise the formation of the bulk layer. The bulk layer can be deposited by a cyclical deposition process (step 822 and associated sub-steps 824 and 826, as well the deposition cycle loop 828). In some embodiments the cyclical deposition processes comprise an atomic layer deposition process. In particular examples, the cyclical deposition process is a selective deposition process (e.g., selective ALD), where the bulk layer is selectively and/or preferentially deposited within the recessed feature thereby enabling bottom-up gap-fill of the recessed feature. In such examples the selectivity of the cyclical deposition process can be enabled or promoted by the inherent surface properties of bulk layer deposition on the metal containing layer (i.e., the seed layer) relative to the other surfaces in and proximate to the recessed feature. In some embodiments the selectivity of the bulk layer formed on the metal containing layer (i.e., the lower surface of the recessed feature) is at least about 30%. In some embodiments selectivity is at least 50%. In some embodiments selectivity is at least 75%, or greater than 85%. In some embodiments selectivity is at least 90% or at least 93%. In some embodiments selectivity is at least 95% or at least 98%. In some embodiments selectivity is at least 99% or even at least 99.5%. In some embodiments the selectivity can change over the duration or thickness of a deposition. It should be noted that a partially selective process can result in a fully selective structure by a post-deposition etch that removes all the deposited material from over the second material without removing the entirety of the deposited material from within the recessed feature.

In accordance with examples of the disclosure, and referring again to FIG. 8, the step of depositing the bulk layer can comprise performing at least one deposition cycle of a cyclical deposition process (step 822), where each deposition cycle includes, introducing a first bulk metal precursor into the reaction chamber to form an absorbed metal species on the metal containing layer (sub-step 824) and introducing a second bulk metal precursor into the reaction chamber to react with the absorbed species to form the bulk layer on the metal containing layer (sub-step 826). Sub-steps 824 and 826 can be repeated as illustrated by deposition cycle loop 828. In particular examples, a deposition cycle (e.g., sub-steps 824 and 826) include intervening purging cycles. In additional examples a deposition cycle is repeated until a sufficient thickness of the bulk layer has been deposited to fill the recessed feature. In such examples the recessed feature is filled from the bottom-up (i.e., initiating from the metal containing layer) and by doing so the bulk layer disposed within the recessed feature is free of a seam. In additional embodiments sub-step 824 and 826 can be initiated and/or terminated in any order. Yet further, cyclical deposition process (step 822) can include one or more (e.g., 1-10 or 1-5) sub-steps sub-step 824 and/or 826 prior to proceeding to the other of sub-step 824 or 826. In some embodiments each deposition cycle can also include one or more additional sub-steps which can be performed during each deposition cycle or during select deposition cycles of the sequence.

In accordance with examples of the disclosure, the bulk layer can comprise one or more of a metal, metal oxide, metal nitride, metal carbide, and the like. In some embodiments the bulk metal layer may comprise one or more of the materials described previously with reference to the metal containing layer. In particular examples, the bulk layer comprises at least one of titanium, aluminum, niobium, tungsten, tantalum, cobalt, ruthenium, and molybdenum. In such examples, the first bulk metal precursor can include at least one of a titanium precursor, an aluminum precursor, a niobium precursor, a tungsten precursor, a cobalt precursor, a ruthenium precursor, and a molybdenum precursor. In some embodiments the first bulk metal precursor may contain a metal species the same as the metal species introduced in the SIS process (806). For example, in particular examples, the first bulk metal precursor comprises at least one of a metal halide (e.g., a metal chloride, or a metal oxychloride), and a metal-organic. As a non-limiting example, the bulk layer may comprise titanium and the first bulk metal precursor may comprise at least one of TiCl₄, TiI₄, TiF₄, and a titanium metal-organic precursor. As a further non-limiting example, the bulk layer may comprise molybdenum and the first bulk metal precursor may comprise at least one of MoCl₅, MoF₆, MoO₂Cl₂, MoOCl₄, and a molybdenum metal-organic precursor.

In accordance with examples of the disclosure, the second bulk metal precursor (e.g., an additional precursor or co-reactant) comprises one or more of an oxygen reactant, a nitrogen reactant, a carbon reactant, or a reducing agent, as previously described above with reference to the formation of the metal containing layer.

As described above, the metal containing layer can be employed as a nucleation layer (or a series of nucleation sites) for the bulk layer.

In some embodiments the metal containing layer may comprise a first metal and the bulk layer may also comprise the first metal (i.e., the metal containg layer and the bulk layer both comprise the same metal species). In particular example, the metal containing layer is a titanium seed layer, and the bulk layer is also a bulk titanium layer. In an additional example, the metal containing layer is a molybdenum seed layer, and the bulk layer is also a molybdenum layer, i.e., a bulk molybdenum layer. In an additional example, the metal containing layer comprises a ruthenium-containing layer (e.g., ruthenium tantalum nitride) and the bulk layer is also a ruthenium-containing layer.

In some embodiments, the metal containing layer is a first metal and the bulk layer is a different second metal (i.e., the metal containing layer and bulk layer are composed of different metals). In a particular example, the metal containing layer is a titanium layer and the bulk layer is also a molybdenum layer. In an additional example, the metal containing layer comprises a ruthenium-containing layer (e.g., ruthenium tantalum nitride) and the bulk layer is a non-ruthenium-containing layer.

Forming the bulk layer by the cyclical deposition process (step 822), as described above, may be further illustrated with reference to FIG. 14. In accordance with examples of the disclosure, FIG. 14 illustrates a structure 1400 which comprises the structure 1300 (of FIG. 13) after forming the bulk layer. As illustrated in FIG. 14 the structure 1400 includes a bulk layer 1420 disposed over (e.g., on) the metal containing layer 1318. In addition, the bulk layer 1420 is illustrated as fully filling the recessed feature 904 without the formation of a seam within the recessed feature 904.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A method of forming a structure on a substrate, the method comprising:
at the substrate including a photosensitive layer on a surface of the substrate;
irradiating select regions of the photosensitive layer with electromagnetic radiation thereby forming a first region having a first concentration of —OH groups and a second region having a second concentration of —OH, wherein the first concentration of —OH groups is greater than the second first concentration of —OH groups;
performing a sequential infiltration synthesis process thereby forming a first infiltrated photosensitive layer in the first region, a non-infiltrated layer disposed below the first infiltrated photosensitive layer, and a second infiltrated photosensitive layer in the second region;
removing the first infiltrated photosensitive layer;
removing the non-infiltrated layer; and
removing a residual component of the second infiltrated photosensitive layer thereby forming a metal containing layer on the surface of the substrate.

2. The method of claim 1, wherein performing the sequential infiltration synthesis process comprising executing one more repeated infiltration cycles, each infiltration cycle comprising at least introducing a first reactant comprising a metal species into a reaction chamber.

3. The method of claim 2, wherein each infiltration cycle further comprises introducing a second reactant into the reaction chamber, the second reactant comprising one or more of an oxygen reactant, a nitrogen reactant, a carbon reactant, or a reducing agent.

4. The method of claim 2, wherein the metal species comprises one or more of aluminum, hafnium, titanium, niobium, tungsten, cobalt, ruthenium, silicon, germanium, and molybdenum.

5. The method of claim 1, wherein removing the first infiltrated photosensitive layer comprises contacting the first infiltrated photosensitive layer with an etchant to expose the non-infiltrated layer.

6. The method of claim 1, wherein removing the non-infiltrated layers and the residual component of the second infiltrated photosensitive layer comprises contacting the non-infiltrated layer and the second infiltrated photosensitive layer with a plasma generated from an oxygen containing gas.

7. A method of filling a recessed feature, the method comprising:
at a substrate comprising the recessed feature and a photosensitive layer disposed over the recessed feature;
irradiating the photosensitive layer with electromagnetic radiation having a wavelength equal to or less than an upper dimension of the recessed feature thereby forming a first region in the photosensitive layer having a first concentration of —OH groups and a second region in the photosensitive layer having a second concentration of —OH, wherein the first concentration of —OH groups is greater than the second first concentration of —OH groups;
performing a sequential infiltration synthesis process thereby forming a first infiltrated photosensitive layer in the first region, a non-infiltrated layer disposed below the first infiltrated photosensitive layer, and a second infiltrated photosensitive layer in the second region;
removing the first infiltrated photosensitive layer;
removing the non-infiltrated layer;
removing a residual component of the second infiltrated photosensitive layer to form a metal containing layer disposed at a lower surface of the recessed feature; and
forming a bulk layer directly on the metal containing layer, wherein the bulk layer fills the recessed feature.

8. The method of claim 7, wherein performing the sequential infiltration synthesis process comprises executing one more repeated infiltration cycles, each infiltration cycle comprising at least introducing a first reactant comprising a metal precursor including a metal species into a reaction chamber.

9. The method of claim 8, wherein each infiltration cycle further comprises introducing a second reactant into the reaction chamber, the second reactant comprising one or more of an oxygen reactant, a nitrogen reactant, or a carbon reactant into the reaction chamber.

10. The method of claim 8, wherein the metal species comprises one or more of aluminum, hafnium, titanium, niobium, tungsten, cobalt, ruthenium, silicon, germanium, and molybdenum.

11. The method of claim 1, wherein the photosensitive layer comprises an organic layer.

12. The method of claim 7, wherein the residual component comprises a residual organic component and removing the residual organic component comprises contacting the residual organic component with a plasma generated from an oxygen containing gas.

13. The method of claim 8, wherein forming the bulk layer directly on the metal containing layer comprises depositing the bulk layer by a cyclical deposition process.

14. The method of claim 13, wherein the bulk layer comprises one or more of a metal, a metal oxide, a metal nitride, and a metal carbide.

15. The method of claim 13, wherein the bulk layer and the metal containing layer both comprise the metal species.

16. The method of claim 13, wherein the bulk layer is different to the metal containing layer.

17. The method of claim 7, further comprising thermally treating the photosensitive layer in an ammonia (NH₃) ambient prior to performing the sequential infiltration synthesis process.

18. A lithography-free method of bottom-up gap filling of a recessed feature, the method comprising:
at a substrate comprising an organic photosensitive layer disposed on the recessed feature, wherein the recessed feature comprises an upper dimension, a lower surface, and an upper surface;
irradiating the organic photosensitive layer with electromagnetic radiation having a wavelength equal to or less than the upper dimension of the recessed feature thereby forming a first region in the organic photosensitive layer having a first concentration of —OH groups and a second region in the organic photosensitive layer having a second concentration of —OH, wherein the first concentration of-OH groups is greater than the second first concentration of —OH groups;
thermally treating the organic photosensitive layer in an ammonia (NH₃) ambient;
performing at least one infiltration cycle of a sequential infiltration synthesis (SIS) sequence to introduce a metal species into the organic photosensitive layer thereby forming a first metal infiltrated layer in the first region, a second metal infiltrated region in the second region, and a non-infiltrated layer, wherein the metal species is selected from a group consisting of the metal species comprises one or more of aluminum, hafnium, titanium, niobium, tungsten, cobalt, ruthenium, silicon, germanium, and molybdenum;
contacting the first metal infiltrated layer with an etchant to remove the first metal infiltrated layer;
contacting the non-infiltrated layer and a residual organic component of the second metal infiltrated region with a plasma generated from an oxygen reactant thereby at least partially filling the recessed feature with a metal containing layer.

19. The method of claim 18, wherein the metal containing layer fills the recessed feature to the upper surface without the formation of a seam.

20. The method of claim 18, wherein the metal containing layer partially fills the recessed feature and a bulk layer is deposited on the metal containing layer to fill the recessed feature to the upper surface without the formation of a seam.
